(19) United States
(12) Patent Application Publication
(10) Pub. No.: US 2013/0016487 A1
(43) Pub. Date: Jan. 17, 2013

(54) MEMORY ADAPTER RECEIVING DEVICE

(71) Applicant: ZE-YUN WU, Shenzhen City (CN)

(72) Inventor: ZE-YUN WU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/311,566

(22) Filed: Dec. 6, 2011

(30) Foreign Application Priority Data
Jul. 11, 2011 (CN) 201110191985.7

(51) Int. Cl. H05K 5/02

(52) U.S. Cl. 361/756

(57) ABSTRACT

A memory adapter receiving device includes a frame, a number of sliding blocks, and a number of connecting blocks. The frame includes a pair of sliding rails each slidably received in one sliding rail. Each connecting block is connected to one sliding block and is to connected to a memory adapter.

### BACKGROUND

1. Technical Field

The present disclosure relates to receiving devices and, particularly, to a memory adapter receiving device.

2. Description of Related Art

To test a number of memories via employing a number of memory adapters, the memory adapters are first inserted into memory slots of a motherboard one by one, and then to-be-tested memories are inserted into the memory adapters one by one.

After the test is finished, the memory adapters are pulled out of the memory slots of the motherboard one by one, and then the memories are pulled out of the memory adapters one by one. This method of employing repeated operations is inefficient.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is an isometric view of a memory adapter receiving device, in accordance with an exemplary embodiment.

FIG. 2 is an exploded, perspective view of the memory adapter receiving device of FIG. 1.

FIG. 3 is an enlarged view of the circled area III of FIG. 2.

FIG. 4 is an isometric view showing how to use the memory adapter receiving device of FIG. 1.

### DETAILED DESCRIPTION

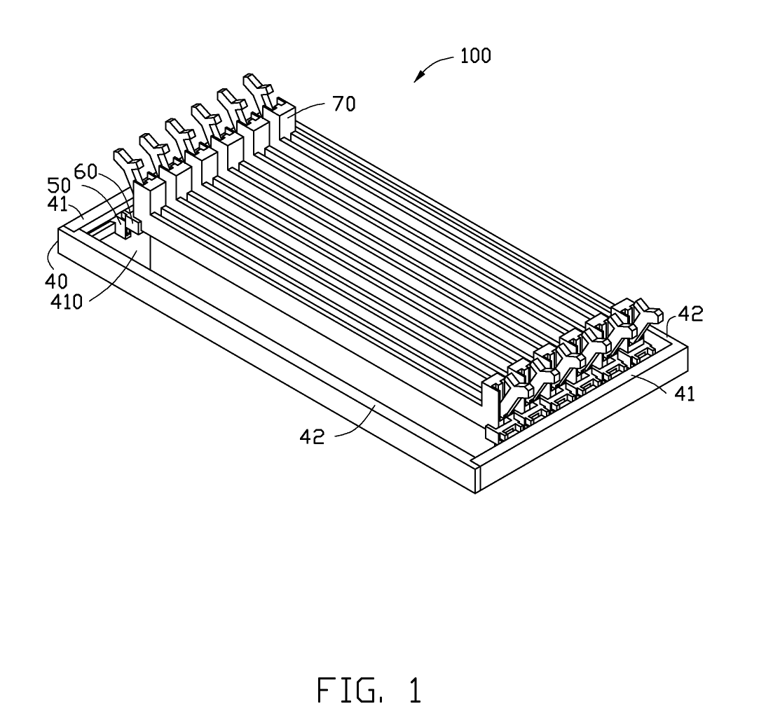

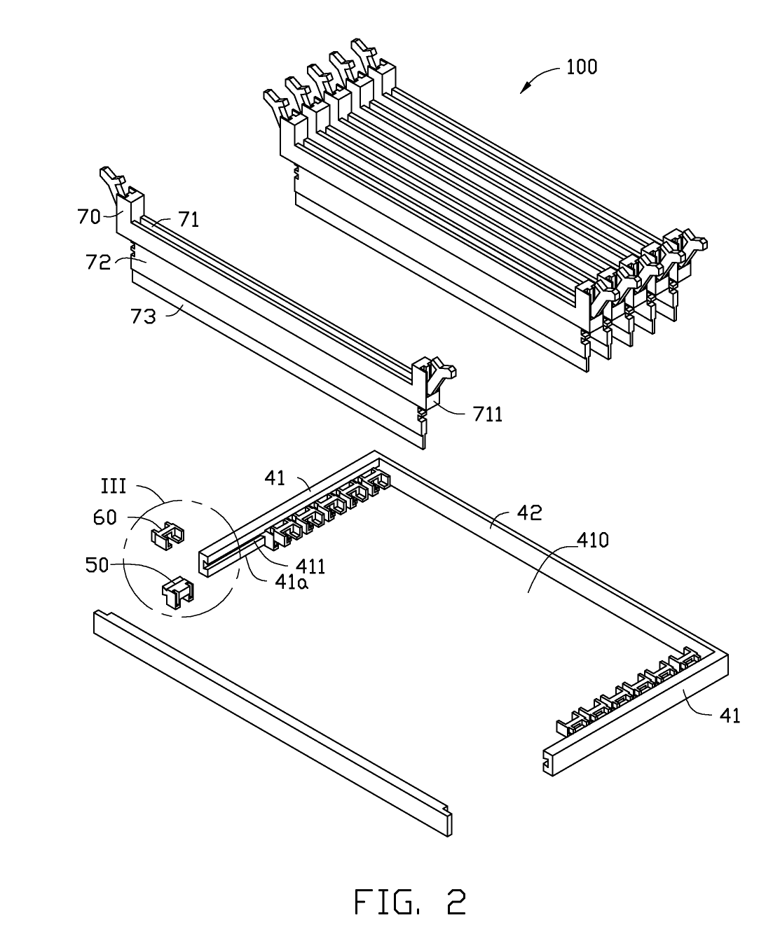

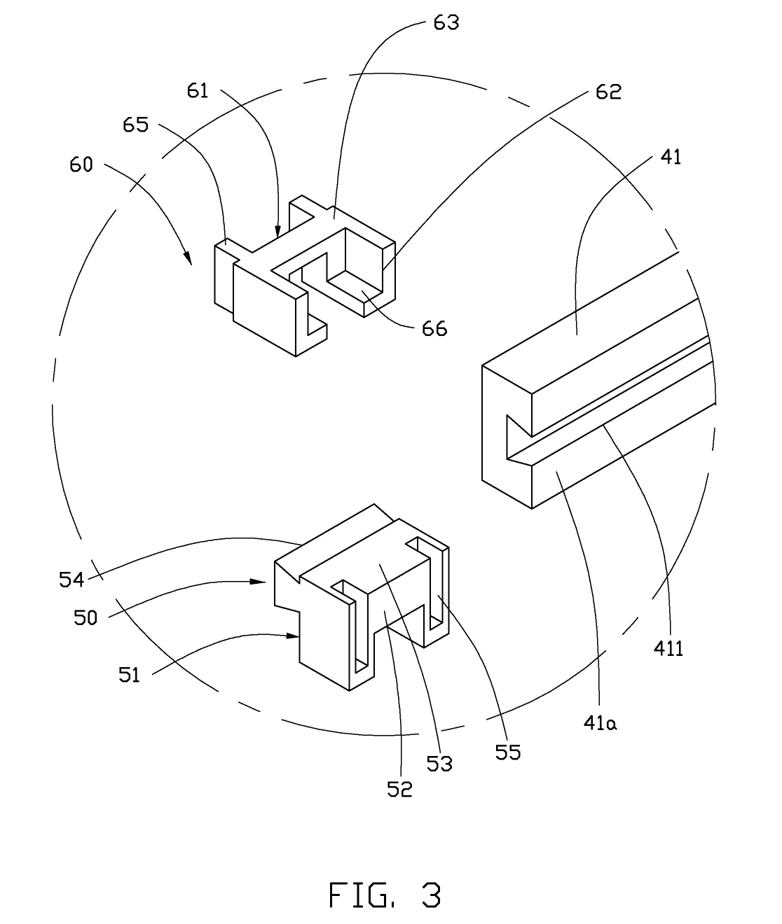

Referring to FIGS. 1-3, an embodiment of a memory adapter receiving device 100 for receiving a number of memory adapters 70 is illustrated. The device 100 includes a frame 40, a number of sliding blocks 50, and a number of connecting blocks 60.

The frame 40 includes two sliding rails 41 and two connecting plates 42. The sliding rails 41 are parallel to each other. The connecting plates 42 are respectively perpendicularly connected to the sliding rails 41, and cooperate with the sliding rails 41 to form a receiving space 410 to receive the memory adapters 70. In this embodiment, the receiving space 410 is substantially rectangular. Each sliding rail 41 includes a sidewall 41a facing the receiving space 410. Each sidewall 41a defines a longitudinal sliding slot 411. The sliding blocks 50 are slidably received in the corresponding sliding slots 411.

Each sliding block 50 includes a first surface 51 facing the sidewall 41a, a second surface 52 opposite to the first surface 51, a third surface 53 perpendicular to the first surface 52 and the second surface 52. A protrusion 54 protrudes from the first surface 51. In this embodiment, the protrusion 54 is substantially trapeziform. The protrusions 54 are the portions of each sliding block 50 slidably received in the sliding slots 411. At least one groove 55 extends from the third surface 53 toward the second surface 52 and creates at least one void in the third surface 53. In this embodiment, two spaced grooves 55 are employed.

Each connecting block 60 includes a fourth surface 61 facing the second surface 52, a fifth surface 62 opposite to the fourth surface 61, and a sixth surface 63 perpendicular to the fourth surface 61 and the fifth surface 62. At least one projection 65 protrudes from the fourth surface 61 and is received in one groove 55 to connect the connecting block 60 to one sliding block 50. In this embodiment, two spaced projections 65 are employed. A recessed portion 62 is formed in the sixth surface 63. The recessed portion 62 extends toward the fourth surface 61 and creates a void in the fifth surface 61.

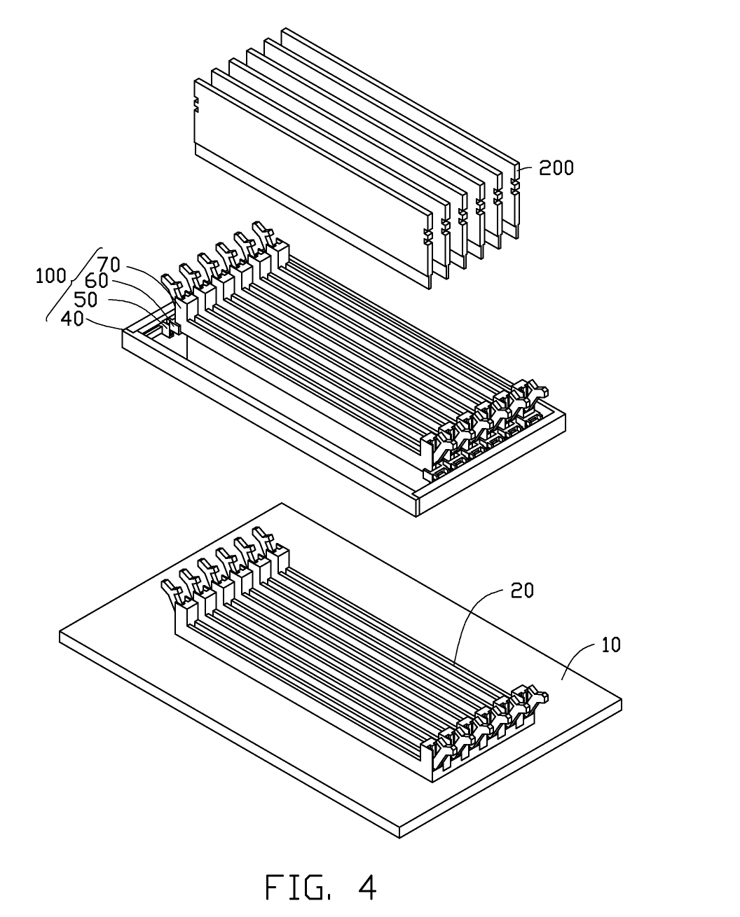

Referring also to FIG. 4, each memory adapter 70 can electrically connect a to-be-tested memory 200 to a memory slot 20 on a motherboard 10. Each memory adapter 70 includes a memory slot 71 to receive one to-be-tested memory 200, a printed circuit board (PCB) 72, and a connecting finger 73. The PCB 72 is arranged to electrically connect the memory slot 71 to the connecting finger 73. The connecting finger 73 can be inserted into one memory slot 20. The memory slot 71 includes two ends 711 each is able to be received in one recessed portion 66.

To test the to-be-tested memories 200, the device 100 is placed on the motherboard 10 to cause each memory adapter 70 received in the device 100 to be inserted into one memory slot 20. Each memory 200 is then inserted into one memory slot 71. At this point, the test for the memories 200 can be started. After the test has been finished, the memory adapters 70 can be pulled out of the memory slots 20 together via exerting force on the device 100.

With such configuration, the memory adapters 70 can be efficiently inserted into and pulled out of the memory slots 20 together.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A memory adapter receiving device comprising:
a frame comprising a pair of sliding rails, the sliding rails being parallel to each other;
a plurality of sliding blocks each slidably received in one of the sliding rails; and
a plurality of connecting blocks each connected to one of the sliding blocks and to be connected to a memory adapter.

2. The memory adapter receiving device as described in claim 1, wherein the frame further comprises two connecting plates connected between the sliding rails, the connecting plates cooperate with the sliding rails to form a receiving space to receive the memory adapters.

3. The memory adapter receiving device as described in claim 2, wherein each of the sliding rails comprises a sidewall facing the receiving space and defining a longitudinal sliding slot, each of the sliding blocks comprises a first surface facing the sidewall and a second surface opposite to the first surface, a protrusion protrudes from the first surface and is slidably received in the sliding slot.

4. The memory adapter receiving device as described in claim 3, wherein each of the sliding blocks further comprises a third surface perpendicular to the first surface and the second surface, at least one groove extends from the third surface toward the second surface and creates at least one void in the third surface, each of the connecting blocks comprises a fourth surface facing the second surface and a fifth surface opposite to the fourth surface, at least one projection protrudes from the fourth surface and is received in the at least one groove.

5. The memory adapter receiving device as described in claim 4, wherein each of the connecting blocks further comprises a sixth surface perpendicular to the fourth surface and the fifth surface, a recessed portion is formed in the fifth surface, the recessed portion extends toward the fourth surface and creates a void in the sixth surface, the recessed portion is to receive a portion of a memory adapter.
